(19) United States
(12) Patent Application Publication
(10) Pub. No.: US 2009/0258234 A1
(43) Pub. Date: Oct. 15, 2009

(54) HOUSING AND METHOD FOR MAKING THE SAME

(75) Inventors: CHWAN-HWA CHIANG, Shindian (TW); YUNG-TA LO, Shindian (TW); TAO GONG, Shenzhen City (CN); XU-FENG AO, Shenzhen City (CN); FENG-YUEN DAI, Shindian (TW)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/420,025

(22) Filed: Apr. 7, 2009

(30) Foreign Application Priority Data
Apr. 11, 2008 (CN) 200810301106.X

(51) Int. Cl. B32B 27/36; B32B 15/00; B05D 1/36; C23C 14/34

(52) U.S. Cl. 428/412; 428/480; 428/457; 428/336; 427/404; 427/258; 204/192.15

(57) ABSTRACT

A housing includes a plastic substrate, a transparent plastic film, and an intermediate layer sandwiched between the plastic substrate and the transparent plastic film. The intermediate layer includes a metallic coating formed on the transparent film and a protective coating formed on and covering the metallic coating. The plastic substrate is moldingly attached to the protective coating.

### BACKGROUND

1. Field of the Invention

The present invention relates to a housing and a method for making a housing.

2. Discussion of the Related Art

Mobile devices, such as mobile telephones, personal digital assistants, or MP3 players, enable consumers to enjoy the convenience of high technology services, almost anytime and at virtually any location. These mobile devices often employ a variety of decorative housings to attract consumers. Electroplating is an attractive and effective process for improving corrosion resistance and metallic appearance of the housings. A typical housing for mobile devices has a metal coating formed thereon by electroplating.

However, electroplated metal coatings can oxidize in moisture.

Therefore, there is room for improvement within the art.

### BRIEF DESCRIPTION OF THE DRAWINGS

Many aspects of the method for making a housing can be better understood with reference to the drawings. The components in the drawing are not necessarily to scale, the emphasis instead being placed upon clearly illustrating the principles of the method for making a housing. Moreover, in the drawings, like reference numerals designate corresponding parts throughout the following view.

FIG. 1 is a section view of an exemplary embodiment of the present housing.

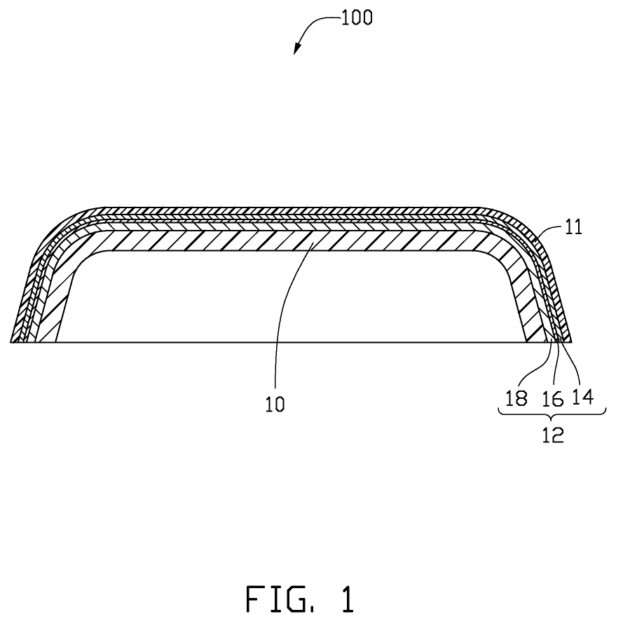

FIG. 2 is a is a flow chart of an exemplary embodiment of a method for making a housing.

### DETAILED DESCRIPTION OF EMBODIMENTS

Referring to the FIG, a housing 100 of the exemplary embodiment includes a plastic substrate 10, a transparent plastic film 11, and an intermediate layer 12 sandwiched between the plastic substrate 10 and the transparent plastic film 11. The intermediate layer 12 includes a decorative coating 14 attached to and under the transparent plastic film 11, a metallic coating 16 attached to and under the decorative coating 14, a protective coating 18 attached to and under the metallic coating 16. The plastic substrate 10 is moldingly attached to the protective coating 18.

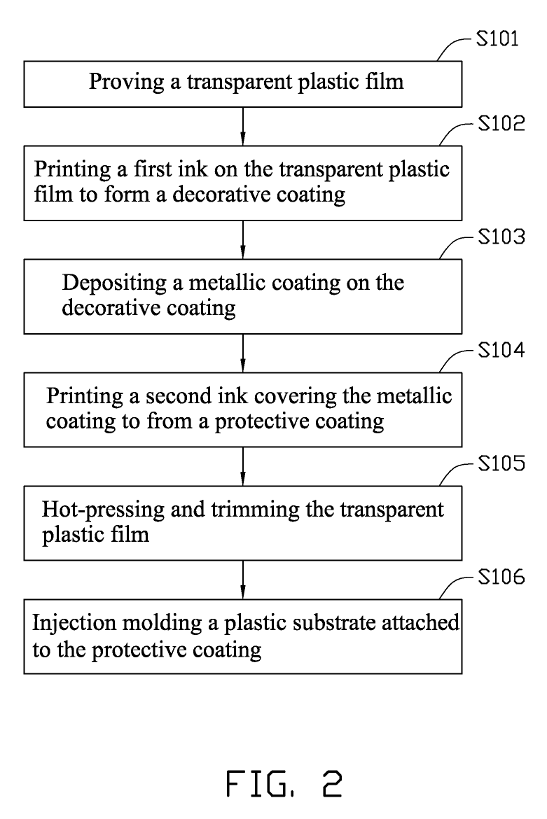

Referring to FIG. 2, a method for making the housing 100 may include following steps S101 to S106.

In step S101, the transparent plastic film 11 is provided. The transparent plastic film 11 may be made of one of poly ethylene terephthalate and polycarbonate.

In step S102, a first ink is printed onto the transparent plastic film 11 by screen printing to form the decorative coating 14. The first ink may be transparent or translucent. The decorative coating 14 may define a pattern. It should be understood that the decorative coating 14 can also be formed of a transparent or translucent paint by spray painting.

In step S103, the metallic coating 16 is formed on the decorative coating 14 by vapor deposition, sputter deposition, ion plating, or chemical plating. That is, the decorative coating 14 is sandwiched between the transparent plastic film 11 and the metallic coating 16, thereby improving the bonding between the transparent plastic film 11 and the metallic coating 16. The metallic coating 16 is made of one of tin, aluminum, titanium, indium, chrome, vanadium, steel, tin-indium alloy, aluminum-silicon alloy, titanium carbide, titanium nitride, titanium oxide, and aluminum oxide, which possess attractive metallic appearances. The thickness of the metallic coating 16 is in a range from about 10 nm to about 0.5 μm.

In step S104, a second ink is applied onto the metallic coating 16 by screen printing to form the protective coating 18. The protective coating 18 covers the metallic coating 16 and protects the metallic coating 16 from oxidation during molding of the plastic substrate 10 in a subsequent step. It should be understood that the protective coating 18 can also be formed of paint by spray painting.

In step S105, the transparent plastic film 11 having the decorative coating 14, the metallic coating 16, and the protective coating 18 coated thereon is hot-pressed and trimmed to form a desired shape.

In step S106, an injection mold is provided. The trimmed transparent plastic film 11 is placed into the injection mold. A melted plastic is then injected into the injection mold, thereby forming the plastic substrate 10 attached to the protective coating 18. The plastic may be selected from a group consisting of polycarbonate, poly methyl methacrylate, poly butylene terephthalate, poly propylene, and mixtures thereof.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A housing, comprising:
a plastic substrate;
a transparent plastic film; and
an intermediate layer sandwiched between the plastic substrate and the transparent plastic film, the intermediate layer including a metallic coating formed on the transparent film and a protective coating formed on the metallic coating, the protective coating covering the metallic coating;
wherein the plastic substrate is moldingly attached to the protective coating.

2. The housing as claimed in claim 1, wherein at least one sides of the transparent film has a decorative coating coated thereon, the decorative coating being sandwiched between the transparent plastic film and the metallic coating.

3. The housing as claimed in claim 2, wherein the decorative coating is made of one of ink and paint.

4. The housing as claimed in claim 2, wherein the decorative coating is transparent or translucent.

5. The housing as claimed in claim 1, wherein the transparent film made of one of poly ethylene terephthalate and polycarbonate.

6. The housing as claimed in claim 1, wherein the metallic coating is made of one selected from a group consisting of tin, aluminum, titanium, indium, chrome, vanadium, steel, tin-indium alloy, aluminum-silicon alloy, titanium carbide, titanium nitride, titanium oxide, and aluminum oxide.

7. The housing as claimed in claim 1, wherein the thickness of the metallic coating 16 is in a range from about 10 nm to about 0.5 μm.

8. The housing as claimed in claim 1, wherein the protective coating is made of one of ink and paint.

9. A method for making a housing, comprising the steps of:
proving a transparent plastic film;
forming a decorative coating onto the plastic film;
forming a metallic coating onto the decorative coating;
forming a protective coating onto the metallic coating; and
injection molding a substrate onto the protective coating.

10. The method as claimed in claim 9, wherein the transparent film made of one of poly ethylene terephthalate and polycarbonate.

11. The method as claimed in claim 9, wherein the decorative coating is made of ink and formed by screen printing.

12. The method as claimed in claim 9, wherein the decorative coating is made of painting and formed by spray painting.

13. The method as claimed in claim 9, wherein the metallic coating is made of one selected from a group consisting of tin, aluminum, titanium, indium, chrome, vanadium, steel, tin-indium alloy, aluminum-silicon alloy, titanium carbide, titanium nitride, titanium oxide, and aluminum oxide.

14. The method as claimed in claim 13, wherein the metallic coating is formed by one of vapor deposition, sputter deposition, ion plating, and chemical plating.

15. The method as claimed in claim 13, wherein the metallic coating the thickness of the metallic coating 16 is in a range from about 10 nm to about 0.5 μm.

16. The method as claimed in claim 9, wherein the protective coating is made of ink and formed by screen printing.

17. The method as claimed in claim 9, wherein the protective coating is made of painting and formed by spray painting.
